(19) United States
(12) Patent Application Publication
(10) Pub. No.: US 2017/0084870 A1
(43) Pub. Date: Mar. 23, 2017

(54) ORGANIC LIGHT EMITTING DEVICE AND DISPLAY DEVICE INCLUDING SAME

(71) Applicant: SAMSUNG DISPLAY CO., LTD., Yongin-si (KR)

(72) Inventors: Chulhyun CHOI, Yongin-si (KR); Gunshik KIM, Yongin-si (KR); Hyunji HA, Seoul (KR)

(21) Appl. No.: 15/083,522

(22) Filed: Mar. 29, 2016

(30) Foreign Application Priority Data
Sep. 18, 2015 (KR) 10-2015-0132506

(51) Int. Cl. H01L 51/52

(52) U.S. Cl. CPC H01L 51/5268; H01L 51/5237

(57) ABSTRACT

An organic light emitting device includes a resistance control layer including a first material, a scattering layer on the resistance control layer, an anode including a second material different from the first material, the anode being on the scattering layer and electrically connected to the resistance control layer, a hole transport region on the anode, an emission layer on the hole transport region, an electron transport region on the emission layer, and a cathode on the electron transport region.

### CROSS-REFERENCE TO RELATED APPLICATION

Korean Patent Application No. 10-2015-0132506, filed on Sep. 18, 2015, in the Korean Intellectual Property Office, and entitled: “Organic Light Emitting Device and Display Device Including Same,” is incorporated by reference herein in its entirety.

### BACKGROUND

1. Field

The present disclosure herein relates to an organic light emitting device and a display device including the same, and more particularly, to an organic light emitting device capable of enhancing a viewing angle and a display device including the same.

2. Description of the Related Art

Flat panel display devices can be generally divided into a light emitting type and a light receiving type. The light emitting type flat panel display device includes a flat cathode ray tube, a plasma display panel, an organic light emitting display, and the like. The organic light emitting display that is a self-light emitting type display, has advantages of a wide viewing angle, an excellent contrast, and a fast response rate. Accordingly, the organic light emitting display may be applied to a display device for a mobile device, e.g., a digital camera, a video camera, a camcorder, a personal digital assistant, a smart phone, an ultra-thin notebook, a tablet personal computer, a flexible display device, or the like, a large electronic product, e.g., an ultra-thin television. or the like, or an electrical product, thus being spotlighted.

The organic light emitting display may realize colors by using a principle in which holes and electrons injected from an anode and a cathode recombine in an emission layer to generate excitons, and when the generated excitons drop from an excited state to a ground state, light is emitted.

### SUMMARY

The present disclosure provides an organic light emitting device capable of enhancing a viewing angle.

The present disclosure also provides a display device capable of enhancing a viewing angle.

An embodiment provides a device including a resistance control layer, a scattering layer, an anode, a hole transport region, an emission layer, an electron transport region, and a cathode. The resistance control layer includes a first material. The scattering layer is provided on the resistance control layer. The anode includes a second material different from the first material, is electrically connected to the resistance control layer, and is provided on the scattering layer. The hole transport region is provided on the anode. The emission layer is provided on the hole transport region. The electron transport region is provided on the emission layer. The cathode is provided on the electron transport region.

In an embodiment, the resistance control layer may include a first sub-contact hole and the scattering layer may include a second sub-contact hole overlapping the first sub-contact hole. The anode may contact the resistance control layer in the first sub-contact hole and the scattering layer in the second sub-contact hole.

In an embodiment, the scattering layer may include a resin layer and a scatterer included in the resin layer.

In an embodiment, the scatterer may include at least one of TiO₂, SiO₂, or ZnO.

In an embodiment, the first material may be a metal.

In an embodiment, the first material may include at least one of Ag, Li, Ca, Al, Mg, W, or Ba.

In an embodiment, the second material may be a transparent conductive oxide.

In an embodiment, the cathode may include a metal.

In an embodiment, the cathode may include at least one of Ag, Li, Ca, Al, Mg, W, or Ba.

In an embodiment, the organic light emitting device may further include an auxiliary layer under the resistance control layer. The auxiliary layer may include a transparent conductive oxide.

In an embodiment, the resistance control layer may include a first sub-contact hole, and the scattering layer may include a second sub-contact hole overlapping the first sub-contact hole, and the auxiliary layer may include a third sub-contact hole overlapping each of the first and second sub-contact holes. The anode may contact the resistance control layer in the first sub-contact hole, the scattering layer in the second sub-contact hole, and the auxiliary layer in the third sub-contact hole.

In an embodiment, the organic light emitting device may further include an organic capping layer provided on the cathode.

In an embodiment, a light may be emitted from the anode towards the cathode in the organic light emitting device.

In an embodiment, the hole transport region may include a hole injection layer and a hole transport layer provided on the hole injection layer.

In an embodiment, the electron transport region may include an electron transport layer and an electron injection layer provided on the electron transport layer.

In an embodiment, a display device includes a plurality of pixels. At least one of the pixels includes an organic light emitting device. The organic light emitting device includes a resistance control layer, a scattering layer, an anode, a hole transport region, an emission layer, an electron transport region, and a cathode. The resistance control layer includes a first material. The scattering layer is provided on the resistance control layer. The anode includes a second material different from the first material, is electrically connected to the resistance control layer, and is provided on the scattering layer. The hole transport region is provided on the anode. The emission layer is provided on the hole transport region. The electron transport region is provided on the emission layer. The cathode is provided on the electron transport region.

In an embodiment, the display device may further include a drain electrode connected to the anode and a passivation layer between the drain electrode and the anode. In an embodiment, the passivation layer may include a first contact hole, and the resistance control layer may include a first sub-contact hole overlapping the first contact hole, and the scattering layer may include a second sub-contact hole overlapping each of the first contact hole and the first sub-contact hole. In an embodiment, the drain electrode may be connected to the anode by the first contact hole and the first and second sub-contact holes.

In an embodiment, the display device may further include an auxiliary layer between the passivation layer and the anode. The auxiliary layer may include a third sub-contact hole overlapping each of the first contact hole and the first and second sub-contact holes. In an embodiment, the drain electrode may be connected to the anode by the first contact hole and the first, second, and third sub-contact holes.

The first contact hole and the first, second, and third sub-contact holes may overlap each other.

In an embodiment, the scattering layer may include a resin layer and a scatterer included in the resin layer.

In an embodiment, the scatterer may include at least one of TiO₂, SiO₂, or ZnO.

In an embodiment, the first material may be a metal and the second material may be a transparent conductive oxide and the cathode may include a metal.

### BRIEF DESCRIPTION OF THE DRAWINGS

Features will become apparent to those of ordinary skill in the art by describing in detail exemplary embodiments with reference to the attached drawings, in which:

FIG. 1 schematically illustrates a cross-sectional view of an organic light emitting device according to an embodiment;

FIG. 2 schematically illustrates a cross-sectional view of an organic light emitting device according to an embodiment;

FIG. 3 schematically illustrates a perspective view of a display device according to an embodiment;

FIG. 4 illustrates a circuit diagram of one of pixels included in a display device according to an embodiment;

FIG. 5 illustrates a plan view of one of pixels included in a display device according to an embodiment;

FIG. 6A schematically illustrates a cross-sectional view taken along line I-I′ in FIG. 5; and

FIG. 6B schematically illustrates a cross-sectional view taken along line I-I′ in FIG. 5.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

Throughout the specification, though terms like “first” and “second” are used to describe various components, the components are not limited to these terms. These terms are used only to differentiate one component from another one. For example, without departing from the scope of the present disclosure, a first element could be termed a second element, and similarly a second element could be termed a first element. A singular form, unless otherwise indicated, includes a plural form.

Further, when it is said that a part “comprises,” “includes,” or “has”, it means that the part may further intend to designate features, integers, steps, operations, elements, components, or the combination thereof Further, it means that one or more other features, integers, steps, operations, elements, parts or combinations thereof, or the additional possibility are not precluded.

Hereinafter, an organic light emitting device according to an embodiment of the inventive concept will be described.

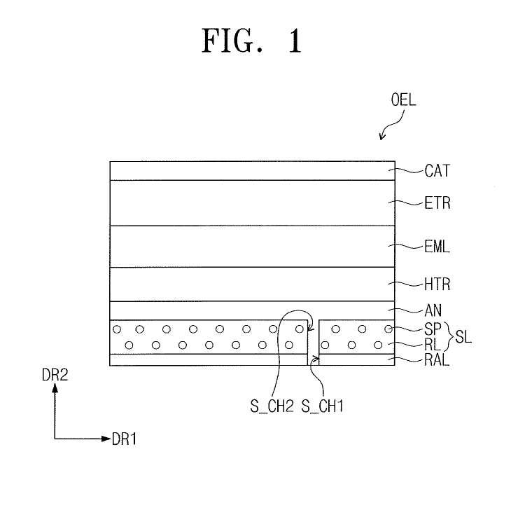

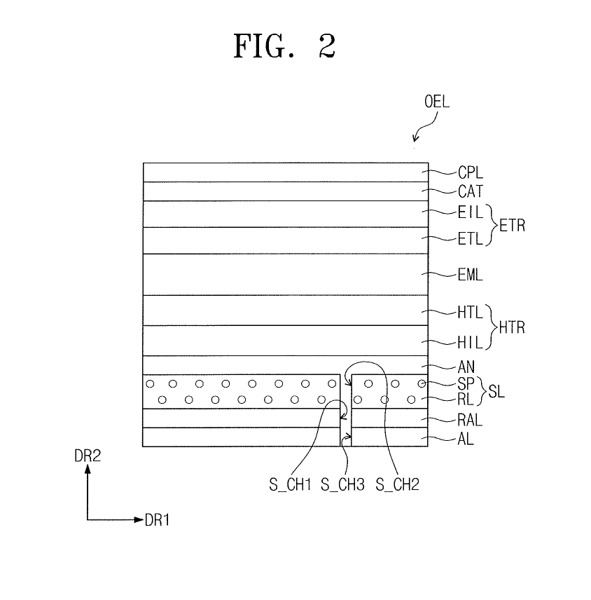

FIG. 1 schematically illustrates a cross-sectional view of an organic light emitting device according to an embodiment. FIG. 2 schematically illustrates a cross-sectional view of an organic light emitting device according to an embodiment.

Referring to FIGS. 1 and 2, an organic light emitting device OEL according to an embodiment may include a resistance control layer RAL, a scattering layer SL, an anode AN, a hole transport region HTR, an emission layer EML, an electron transport region ETR, and a cathode CAT.

The resistance control layer RAL is connected to the anode AN to be able to reduce resistance of the anode AN. The resistance control layer RAL includes a first sub-contact hole S_CH1. The resistance control layer RAL contacts the anode AN in the first sub-contact hole S_CH1.

The resistance control layer RAL includes a first material. The first material may be a metal. Although not particularly limited, the first material may include any suitable material, e.g., at least one of Ag, Li, Ca, Al, Mg, W, or Ba.

The scattering layer SL is provided on the resistance control layer RAL. The scattering layer SL may scatter light emitted from the emission layer EML. For example, when the organic light emitting device OEL has a resonance distance, the scattering layer SL may scatter light emitted from the emission layer EML so that the organic light emitting device OEL is not resonant. That is, even when the organic light emitting device OEL has a resonance distance, the scattering layer SL may allow the organic light emitting device OEL to have a non-resonant structure.

The scattering layer SL includes a second sub-contact hole S_CH2. The second sub-contact hole S_CH2 overlaps the first sub-contact hole S_CH1. The second sub-contact hole S_CH2 may correspond to the first sub-contact hole S_CH1 when viewed in cross section, e.g., the second sub-contact hole S_CH2 may completely overlap and be in fluid communication with the first sub-contact hole S_CH1 to define a single and uniform hole therewith. The scattering layer SL, e.g., directly, contacts the anode AN in the second sub-contact hole S_CH2.

The scattering layer SL may include a resin layer RL and scatterers SP included in the resin layer RL, e.g., the scatterers SP may be particles uniformly dispersed within the resin layer RL. Although not particularly limited, the resin layer RL may include any suitable material, e.g., a silicone resin or a photoresist resin. Although not particularly limited, the scatterer SP may include any suitable material, e.g., at least one of TiO₂, SiO₂, or ZnO.

The scatterers SP may have a refractive index of, e.g., about 1.2 to about 2.5. When the scatterer SP has a refractive index less than about 1.2, the scattering layer SL has difficulty in sufficiently scattering light emitted from the emission layer EML, and thus, the organic light emitting device OEL has difficulty in being non-resonant. In addition, when the scatterer SP has a refractive index more than about 2.5, among the light emitted from the emission layer EML and provided to the scattering layer SL, the amount of light which is not scattered and is provided from the anode AN toward the cathode CAT is reduced so that light efficiency of the organic light emitting device OEL may be reduced.

The anode AN is provided on the scattering layer SL, e.g., the scattering layer SL may be between the anode AN and the resistance control layer RAL. While the anode AN contacts the scattering layer SL, the anode AN and the scattering layer SL are separate layers, e.g., the anode AN is made of a different material than the scattering layer SL. The anode AN may be a pixel electrode or a positive electrode. The anode AN is connected to the resistance control layer RAL. The anode AN is connected to the resistance control layer RAL through the first and second sub-contact holes S_CH1 and S_CH2, e.g., a portion of the anode AN extends through the scattering layer SL, i.e., through the first and second sub-contact holes S_CH1 and S_CH2, to contact the resistance control layer RAL.

The anode AN includes a second material different from the first material of the resistance control layer RAL. The second material may be a transparent conductive oxide. Although not particularly limited, the second material may include any suitable material including at least one of, e.g., indium tin oxide (ITO), indium zinc oxide (IZO), zinc oxide (ZnO), or indium tin zinc oxide (ITZO).

The hole transport region HTR is provided on the anode AN. The hole transport region HTR may include at least one of a hole injection layer HIL, a hole transport layer HTL, a buffer layer, or an electron blocking layer.

For example, as illustrated in FIG. 1, the hole transport region HTR may have a single layer structure formed of a single material or a single layer structure formed of a plurality of materials different form each other. In another example, as illustrated in FIG. 2, the hole transport region HTR may have a multi-layer structure having a plurality of layers formed of a plurality of materials different from each other.

In detail, the hole transport region HTR may have a single layer structure formed of a plurality of different materials or a structure of the hole injection layer HIL/the hole transport layer HTL, the hole injection layer HIL/the hole transport layer HTL/the buffer layer, the hole injection layer HIL/the buffer layer, the hole transport layer HTL/the buffer layer, or the hole injection layer HIL/the hole transport layer HTL/the electron blocking layer, which are sequentially stacked from the anode AN, but is not limited thereto. The hole transport region HTR may be formed by using any of various methods, e.g., a vacuum deposition method, a spin coating method, a casting method, a Langmuir-Blodgett method, an inkjet printing method, a laser printing method, and a laser induced thermal imaging (LITI) method.

When the hole transport region HTR includes the hole injection layer HIL, the hole transport region HTR may include, but not limited to, a phthalocyanine compound such as copper phthalocyanine; N,N′-diphenyl-N,N′-bis-[4-(phenyl-m-tolyl-amino)-phenyl]-biphenyl-4,4′-diamine (DNTPD), 4,4′,4″-tris(3-methylphenylphenylamino) triphenylamine (m-MTDATA), 4,4′,4″-Tris(N,N-diphenylamino)triphenylamine (TDATA), 4,4′,4″-tris{N,-(2-naphthyl)-N-phenylamino}-triphenylamine (2TNATA), poly(3,4-ethylenedioxythiophene)/Poly(4-styrenesulfonate) (PEDOT/PSS), polyaniline/dodecylbenzenesulfonic acid (PANI/DBSA), polyaniline/camphor sulfonicacid (PANI/CSA), (polyaniline)/poly(4-styrenesulfonate) (PANI/PSS).

When the hole transport region HTR includes the hole transport layer HTL, the hole transport region HTR may include, but not limited to, a carbazole derivative such as N-phenyl carbazole, polyvinyl carbazole; a fluorine derivative; a triphenylamine derivative such as N,N′-bis(3-methylphenyl)-N,N′-diphenyl-[1,1-biphenyl]-4,4′-diamine (TPD). 4,4′,4″-tris(N-carbazolyl)triphenylamine (TCTA); N,N-di(1-naphthyl)-N,N′-diphenylbenzidine (NPB), 4,4′-Cyclohexylidene bis[N,N-bis(4-methylphenyl)benzenamine] (TAPC).

The hole transport region HTR may have a thickness of about 100 Å to about 10,000 Å, e.g., about 100 Å to about 1,000 Å. When the hole transport region HTR includes both the hole injection layer HIL and the hole transport layer HTL, the hole injection layer HIL may have a thickness of about 100 Å to about 10,000 Å, e.g., about 100 Å to about 1,000 Å, and the hole transport layer HTL may have a thickness of about 50 Å to about 2000 Å, e.g., about 100 Å to about 1,500 Å. When the thicknesses of the hole transport layer HTR, the hole injection layer HIL, and the hole transport layer HTL satisfy the above mentioned ranges, satisfactory hole transport characteristics may be obtained without a substantial rise in driving voltage.

The hole transport region HTR may further include a charge generating material to improve the conductivity thereof in addition to the above-mentioned material(s). The charge generating material may be uniformly or non-uniformly dispersed inside the hole transport region HTR. The charge generating material may be, e.g., a p-dopant material. The p-dopant material may be, but not limited to, one of a quinine derivative, a metal oxide, and a cyano group-containing compound. For example, a non-limiting example of the p-dopant material may include, but not limited to, a quinone derivative e.g., tetracyanoquinodimethane (TCNQ) or 2,3,5,6-tetrafluoro-tetracyanoquinodimethane (F4-TCNQ); and a metal oxide e.g., tungsten oxide or molybdenum oxide.

As previously mentioned, the hole transport region HTR may further include at least one of a buffer layer or an electron blocking layer in addition to the hole injection layer HIL and the hole transport layer HTL. The buffer layer may enhance light emitting efficiency by compensating for a resonance distance according to a wavelength of light emitted from the emission layer EML. A material which may be included in the hole transport region HTR may be used as a material included in the buffer layer. The electron blocking layer is a layer playing a role of preventing electrons from being injected into the hole transport region HTR from the electron transport region ETR.

The emission layer EML is provided on the hole transport region HTR. The emission layer EML may have a single layer structure formed of a single material, a single layer structure formed of a plurality of materials different form each other, or a multi-layer structure having a plurality of layers formed of a plurality of materials different from each other.

Although not limited, the emission layer EML may be formed of any suitable material, e.g., a material emitting red, green, or blue light, and may include a fluorescent material or a phosphorescent material. Further, the emission layer EML may include a host material and a dopant material.

Although not particularly limited, the host material may include any suitable host material, e.g., tris(8-hydroxyquinolino)aluminum (Alq3), 4,4′-bis(N-carbazolyl)-1,1′-biphenyl (CBP), poly(n-vinylcabazole) (PVK), 9,10-di(naphthalene-2-yl)anthracene (ADN), 4,4′,4″-Tris(carbazol-9-yl)-triphenylamine (TCTA), 1,3,5-tris(N-phenylbenzimidazole-2-yl)benzene (TPBi), 3-tert-butyl-9,10-di(naphth-2-yl)anthracene (TBADN), distyrylarylene (DSA), 4,4′-bis(9-carbazolyl)-2,2′-dimethyl-biphenyl (CDBP), 2-Methyl-9,10-bis(naphthalen-2-yl)anthracene (MADN) or the like.

When the emission layer EML emits red light, the emission layer EML may include, e.g., a fluorescent material including PBD:Eu(DBM)3(Phen)(tris(dibenzoylmethanato)phenanthroline europium) or perylene. When the emission layer EML emits red light, the dopant material included in the emission layer EML may be selected from a metal complex or an organometallic complex such as acac(bis(1-phenylisoquinoline)acetylacetonate iridium (PIQIr), acac(bis(1-phenylquinoline)acetylacetonate iridium (PQIr), tris(1-phenylquinoline)iridium (PQIr), and octaethylporphyrin platinum (PtOEP).

When the emission layer EML emits green light, the emission layer EML may include, e.g., a fluorescent material including tris(8-hydroxyquinolino)aluminum (Alq3). When the emission layer EML emits green light, the dopant material included in the emission layer EML may be selected from a metal complex or an organometallic complex, e.g., Ir(ppy)3(fac-tris(2-phenylpyridine)iridium).

When the emission layer EML emits a blue light, the emission layer EML may include, e.g., a fluorescent material including any one of spiro-DPVBi, spiro-6P, distyryl-benzene (DSB), distyryl-arylene (DSA), polyfluorene (PFO) polymers, and poly(p-phenylene vinylene (PPV) polymers. When the emission layer EML emits blue light, the dopant material included in the emission layer EML may be selected from a metal complex or an organometallic complex, e.g., (4,6-F2ppy)2Irpic. The emission layer EML will be described in more detail below.

The electron transport region ETR is provided on the emission layer EML. The electron transport region ETR may include, but not limited to, at least one of the hole blocking layer, the electron transport layer ETL, or the electron injection layer EIL.

When the electron transport region ETR includes the electron transport layer, the electron transport region ETR may include, but not limited to, Tris(8-hydroxyquinolinato)aluminum (Alq3), 1,3,5-Tri(1-phenyl-1H-benzo[d]imidazol-2-yl)phenyl (TPBi), 2,9-Dimethyl-4,7-diphenyl-1,10-phenanthroline (BCP), 4,7-Diphenyl-1,10-phenanthroline (Bphen), 3-(4-Biphenylyl)-4-phenyl-5-tert-butylphenyl-1,2,4-triazole (TAZ), 4-(Naphthalen-1-yl)-3,5-diphenyl-4H-1,2,4-triazole (NTAZ), 2-(4-Biphenylyl)-5-(4-tert-butylphenyl)-1,3,4-oxadiazole (tBu-PBD), Bis(2-methyl-8-quinolinolato-N1,O8)-(1,1′-Biphenyl-4-olato)aluminum (BAlq), berylliumbis(benzoquinolin-10-olate) (Bebq2), 9,10-di(naphthalene-2-yl)anthracene (ADN), and a mixture thereof.

The thickness of the electron transport layer ETL may range from about 100 Å to about 1,000 Å, e.g., from about 150 Å to about 500 Å. When the thickness of the electron transport layer ETL satisfies the above mentioned range, satisfactory electron transport characteristics may be obtained without a substantial rise in driving voltage.

When the electron transport region ETR includes the electron injection layer EIL, the electron transport region ETR may use, but not limited to, LiF, Lithium quinolate (LiQ), Li₂O, BaO, NaCl, CsF, a lanthanide metal such as Yb, or a metal halide such as RbCl, RbI. The electron injection layer EIL may also include a material in which an electron transport material and an insulating organo metal salt are mixed. The organo metal salt may be a material having an energy band gap of about 4 eV or higher. In detail, the organic metal salt may include, e.g., metal acetate, metal benzoate, metal acetoacetate. metal acetylacetonate, or metal stearate. The thickness of the electron injection layer EIL may range from about 1 Å to about 100 Å , e.g., from about 3 Å to about 90 Å. When the thickness of the electron injection layer EIL satisfies the above mentioned range, satisfactory electron injection characteristics may be obtained without a substantial rise in driving voltage.

The electron transport region ETR may include the hole blocking layer as mentioned above. The hole blocking layer may include, but not limited to, e.g., at least one of 2,9-dimethyl-4,7-diphenyl-1,10-phenanthroline (BCP) and 4,7-diphenyl-1,10-phenanthroline (Bphen).

The cathode CAT is provided on the electron transport region ETR. The cathode CAT may be a common electrode or a negative electrode. The cathode CAT may include a metal. Although not particularly limited, the cathode CAT may include any suitable material, e.g., at least one of Ag, Li, Ca, Al, Mg, W, or Ba.

The organic light emitting device OEL according to an embodiment may be a top emission type organic light emitting device. In detail, the organic light emitting device OEL according to an embodiment may emit light from the anode AN toward the cathode CAT.

The organic light emitting device OEL according to an embodiment may be designed to have a resonance distance, to include the scattering layer SL, and to allow light emitted from the emission layer EML to be non-resonant even when the cathode includes a metal.

Although not illustrated, the cathode CAT may be connected to an auxiliary electrode. When the cathode CAT is connected to the auxiliary electrode, resistance of the cathode CAT may be reduced.

Referring to FIG. 2, the organic light emitting device OEL according to an embodiment may further include an auxiliary layer AL. The auxiliary layer AL is provided under the resistance control layer RAL.

The auxiliary layer AL includes a third sub-contact hole S_CH3. The third sub-contact hole S_CH3 overlaps each of the first and second sub-contact holes S_CH1 and S_CH2. The third sub-contact hole S_CH3 may correspond to each of the first and second sub-contact holes S_CH1 and S_CH2 when viewed in cross section. The auxiliary layer AL contacts the anode AN in the third sub-contact hole S_CH3.

The auxiliary layer AL may include a transparent conductive oxide. Although not particularly limited, the auxiliary layer AL may include any suitable material, e.g., at least one of indium tin oxide (ITO), indium zinc oxide (IZO), zinc oxide (ZnO), or indium tin zinc oxide (ITZO).

The organic light emitting device OEL according to an embodiment may further include an organic capping layer CPL. The organic capping layer CPL may be provided on the cathode CAT. The organic capping layer CPL may reflect light emitted from the emission layer EML from an upper surface of the organic capping layer CPL toward the emission layer EML. Since the reflected light is amplified inside the organic layer, luminescent efficiency of the organic light emitting device OEL may be improved. The organic capping layer CPL may prevent light from being lost in the cathode CAT of the top emission type organic light emitting device OEL.

Although not limited to, the organic capping layer CPL may be formed of any suitable material, e.g., at least one of N4,N4,N4′,N4′-tetra(biphenyl-4-yl)biphenyl-4,4′-diamine (TPD15), 4,4′,4″-Tris(carbazol sol-9-yl)triphenylamine (TCTA), N,N′-bis(naphthalen-1-yl), or α-NPD(N,N-bis(phenyl)-2,2′-dimethylbenzidine.

Although not illustrated, an encapsulation layer may be provided on the cathode CAT. The encapsulation layer covers the cathode CAT. The encapsulation layer may include at least one of an organic layer or an inorganic layer. The encapsulation layer may be a thin encapsulation layer. The encapsulation layer protects the organic light emitting device OEL.

Referring back to FIGS. 1 and 2, in the organic light emitting device OEL, when voltages are applied to the anode AN and cathode CAT, respectively, holes injected from the anode AN move to the emission layer EML through the hole transport region HTR, and electrons injected from the cathode CAT move to the emission layer EML through the electron transport region ETR. The electrons and the holes recombine in the emission layer EML to generate excitons, and the excitons drop from an excited state to a ground state to emit light.

An organic light emitting device without a scattering layer has a limitation of a narrow viewing angle when a user views an image. In addition, an organic light emitting device having a scattering layer within an anode may have a high power consumption that is required by the scattering layer when an electric field is applied to the anode.

In contrast, the organic light emitting device according to an embodiment includes the scattering layer SL, so a wide viewing angle may be provided to a user when the user views an image. In addition, since the organic light emitting device according to an embodiment includes the scattering layer outside, i.e., under, the anode AN and separated from the anode AN, the organic light emitting device may be driven with low power consumption. Furthermore, the organic light emitting device according to an embodiment includes a resistance control layer RAL electrically connected to the anode AN, so the organic light emitting device may be driven with low power consumption.

Hereinafter, a display device according to an embodiment will be described. In the following description, a detailed description centered on differences from the above-described organic light emitting devices according to embodiments will be provided in detail, and elements that are not described may be deemed described by the above description of the above described organic light emitting devices.

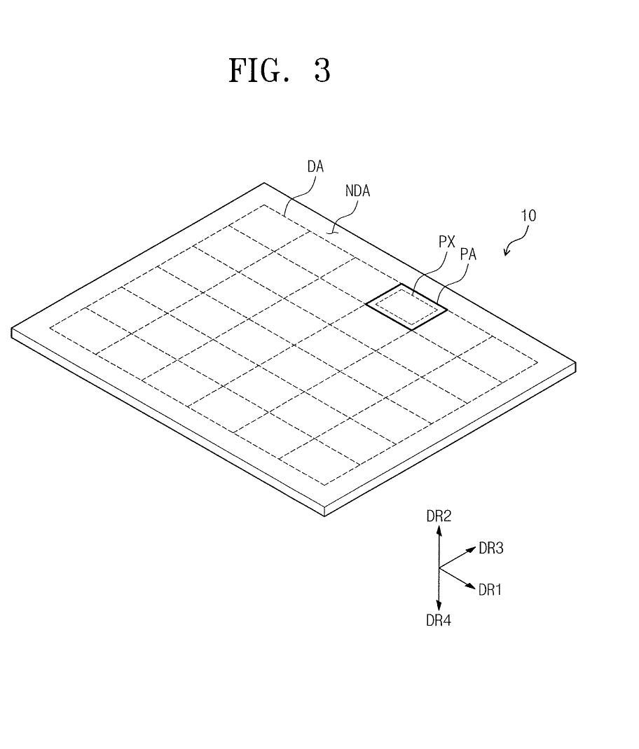

FIG. 3 schematically illustrates a perspective view of a display device according to an embodiment.

Referring to FIG. 3, a display device 10 according to an embodiment may be divided into a display region DA and a non-display region NDA. The display region DA displays an image. When viewed in a thickness direction (for example, D4) of the display device 10, the display region DA may have approximately a rectangular shape, but the embodiment is not limited thereto.

The display region DA includes a plurality of pixel regions PA. The pixel regions PA may be arranged in a matrix shape. A plurality of pixels PX may be arranged in the pixel regions PA. At least one of the pixels PX includes an organic light emitting device (OEL in FIG. 1).

The non-display region NDA does not display an image. When viewed in the thickness direction DR4 of the display device 10, the non-display region NDA may be, e.g., a region surrounding the display region DA. The non-display region NDA may be adjacent to the display region DA in a first direction DR1 and a third direction DR3. The third direction DR3 crosses each of the first and second directions DR1 and DR2.

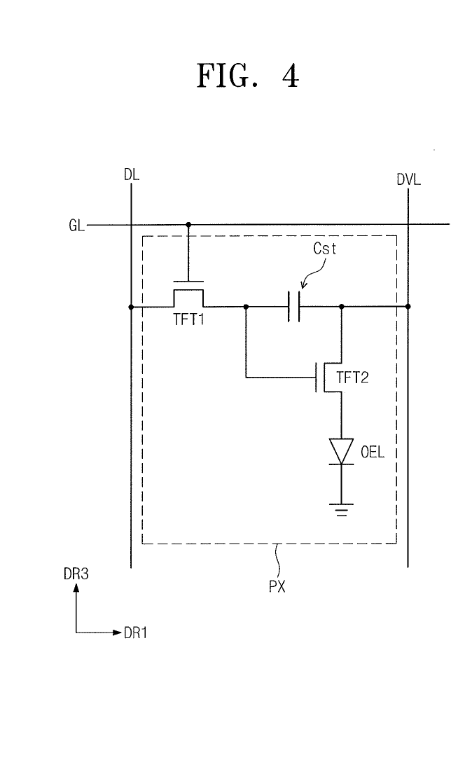

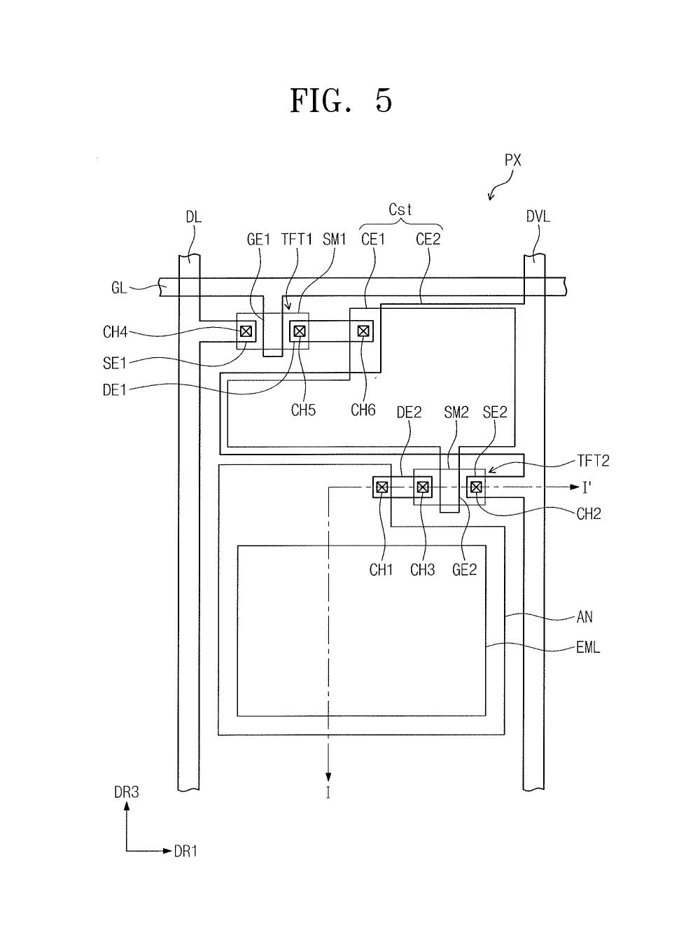

FIG. 4 illustrates a circuit diagram of one of pixels included in a display device according to an embodiment. FIG. 5 illustrates a plan view of one of pixels included in a display device according to an embodiment.

Referring to FIGS. 4 to 5, each of the pixels PX may be connected to a wiring part including gate lines GL, data lines DL, and driving voltage lines DVL. Each of the pixels PX includes thin film transistors TFT1 and TFT2 connected to the wiring part, and the organic light emitting device OEL and a capacitor Cst which are connected to thin film transistors TFT1 and TFT2. Each of the pixels PX may emit light of a specific color, e.g., one of red, green, blue, white, and cyan light.

While FIG. 5 exemplarily illustrates that each of the pixels PX has a rectangular shape when viewed from above, embodiments are not limited thereto, e.g., each of the pixels PX may have at least one of a circular shape, an oval shape, a square shape, a parallelogram shape, a trapezoid shape. or a rhombus shape. In addition, each of the pixels PX may have, e.g., a rectangular shape in which at least one of corners is rounded when viewed from above.

The gate line GL extends in the first direction DR1. The data line DL extends in the third direction DR3 crossing the gate line GL. The driving voltage line DVL extends in the substantially same direction as the data line DL, e.g. the third direction DR3. The gate line GL delivers a scan signal to the thin film transistors TFT1 and TFT2, the data lines DL delivers a data signal to the thin film transistors TFT1 and TFT2, and the driving voltage line DVL provides a driving voltage to the thin film transistors TFT1 and TFT2.

The thin film transistors TFT1 and TFT2 may include a driving thin film transistor TFT2 controlling the organic light emitting device and a switching thin film transistor TFT1 switching the driving thin film transistor TFT2. Although an embodiment describes that each of the pixels PX includes two thin film transistors TFT1 and TFT2, the embodiment is not limited thereto. In another embodiment, each of the pixels PX may include one thin film transistor and one capacitor or may include three or more thin film transistors and two or more capacitors.

The switching thin film transistor TFT1 includes a first gate electrode GE1, a first source electrode SE1, and a first drain electrode DEL The first gate electrode GE1 is connected to the gate line GL and the first source electrode SE1 is connected to the data line DL. The first drain electrode DE1 is connected to a first common electrode CE1 through a fifth contact hole CH5. The switching thin film transistor TFT1 delivers, to the driving thin film transistor TFT2, a data signal applied to the data line DL according to a scan signal applied to the gate line GL.

The driving thin film transistor TFT2 includes a second gate electrode GE2, a second source electrode SE2, and a second drain electrode DE2. The second gate electrode GE2 is connected to the first common electrode CE1. The second source electrode SE2 is connected to the driving voltage line DVL. The second drain electrode DE2 is connected to an anode AN by a first contact hole CH1 and an anode contact hole A_CH. The anode contact hole A_CH includes the first, second, and third sub-contact holes S_CH1 S_CH2, and S_CH3.

The capacitor Cst is connected between the second gate electrode GE2 and the second source electrode SE2 of the driving thin film transistor TFT2 and is charged with and holds a data signal input to the second gate electrode GE2 of the drive thin film transistor TFT2. The capacitor Cst may include the first common electrode CE1 connected to the first drain electrode DE1 through a sixth contact hole CH6 and a second common electrode CE2 connected to the driving voltage line DVL.

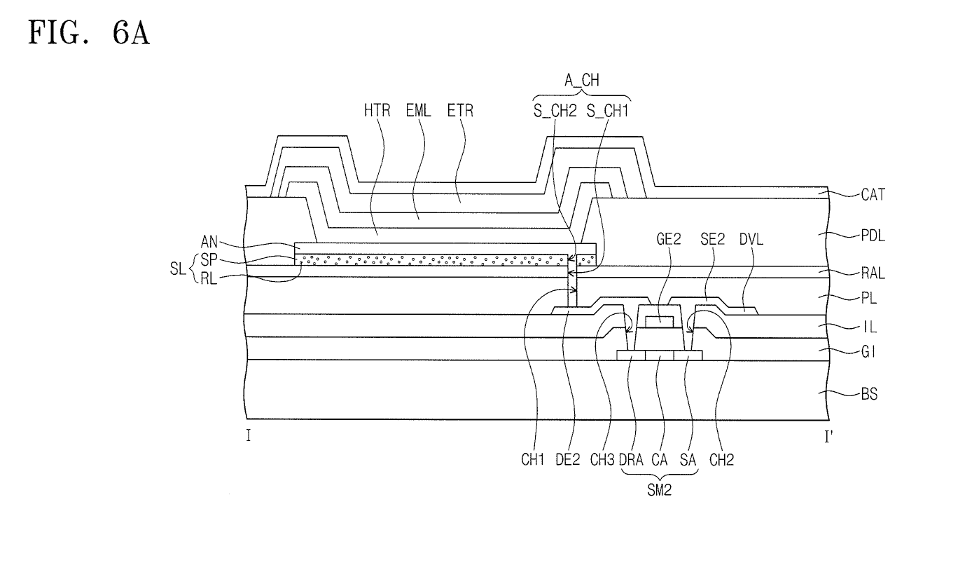

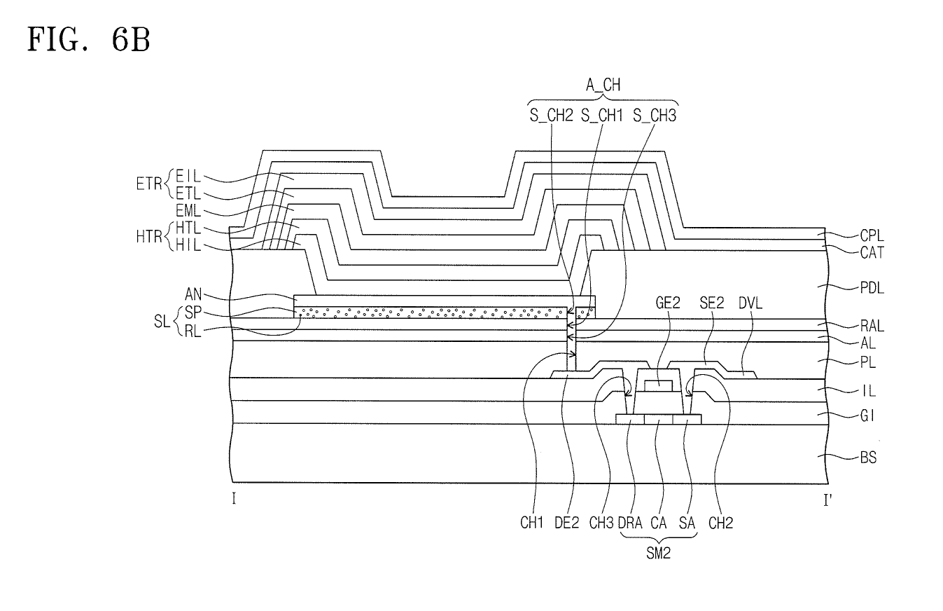

FIG. 6A schematically illustrates a cross-sectional view taken along line I-I′ in FIG. 5. FIG. 6B schematically illustrates a cross-sectional view taken along line I-I′ in FIG. 5.

Referring to FIGS. 4, 5, 6A, and 6B, the display device 10 according to an embodiment may include a base substrate BS on which the thin film transistors TFT1 and TFT2 and the organic light emitting device OEL are stacked.

Although not particularly limited, the base substrate BS may be formed of any suitable material, e.g., an insulating material such as glass, plastic, or a crystal material. An organic polymer forming the base substrate BS may be polyethylene terephthalate (PET), polyethylene naphthalate (PEN), polyimide, polyether sulfone, or the like. The base substrate BS may be selected in consideration of mechanical strength, thermal stability, transparency, surface smoothness, easiness of handling, water resistance, or the like.

A substrate buffer layer may be provided on the base substrate BS. The substrate buffer layer prevents an impurity from diffusing into the switching thin film transistor TFT1 and the driving thin film transistor TFT2. Silicon nitride (SiNₓ), silicon oxide (SiOₓ), silicon oxynitride (SiOₓN_{y}), or the like may form the substrate buffer layer and may be omitted according to a material and a process condition of the base substrate BS.

A first semiconductor layer SM1 and a second semiconductor layer SM2 are provided on the base substrate BS. The first and second semiconductor layers SM1 and SM2 are formed of semiconductor materials and respectively operate as an active layer of each of the switching thin film transistor TFT1 and the driving thin film transistor TFT2. Each of the first and second semiconductor layers SM1 and SM2 includes a source region SA, a drain region DRA, and a channel region CA between the source region SA and drain region DRA. Each of the first and second semiconductor layers SM1 and SM2 may be formed of an organic semiconductor material or an inorganic semiconductor material. The source region SA and the drain region DRA may be doped with an n-type impurity or a p-type impurity.

A gate insulating layer GI is provided on the first and second semiconductor layers SM1 and SM2. The gate insulating layer GI covers the first and second semiconductor layers SM1 and SM2. The gate insulating layer GI may be formed of an organic insulating material or an inorganic insulating material.

First and second gate electrodes GE1 and GE2 are provided on the gate insulating layer GI. The first and second gate electrodes GE1 and GE2 are formed so as to respectively cover regions corresponding to the channel regions CA of the first and second semiconductor layers SM1 and SM2.

An interlayer insulating layer IL is provided on the first and second gate electrodes GE1 and GE2. The interlayer insulating layer IL covers the first and second gate electrodes GE1 and GE2. The interlayer insulating layer IL may be formed of an organic insulating material or an inorganic insulating material.

First source electrode SE1 and first drain electrode DE1 and second source electrode SE2 and second drain electrode DE2 are provided on the interlayer insulating layer IL. The first source electrode SE1 contacts the source region of the first semiconductor layer SM1 through a fourth contact hole CH4 formed in the gate insulating layer GI and the interlayer insulating layer IL and the first drain electrode DE1 contacts the drain region of the first semiconductor layer SM1 through the fifth contact hole CH5 formed in the gate insulating layer GI and the interlayer insulating layer IL.

The second drain electrode DE2 contacts the drain region DRA of the second semiconductor layer SM2 by the third contact hole CH3 formed in the gate insulating layer IL and the interlayer insulating layer IL. The second drain electrode DE2 is connected to the anode AN through the first contact hole CH1 and the anode contact hole A_CH. The second source electrode SE2 contacts the source region SA of the second semiconductor layer SM2 by the second contact hole CH2 formed in the gate insulating layer IL and the interlayer insulating layer IL.

A passivation layer PL is provided on the first source electrode SE1 and the first drain electrode DE1 and the second source electrode SE2 and the second drain electrode DE2. The passivation layer PL may act as a protective film configured to protect the switching thin film transistor TFT1 and the driving thin film transistor TFT2 or a planarization film configured to planarize a top surface of the switching thin film transistor TFT1 and the driving thin film transistor TFT2. The passivation layer PL includes the first contact hole CHL The passivation layer PL contacts the anode AN in the first contact hole CH1.

The organic light emitting device OEL is provided on the passivation layer PL. The organic light emitting device OEL may include the resistance control layer RAL, the scattering layer SL, the anode AN, the hole transport region HTR, the emission layer EML, the electron transport region ETR, and the cathode CAT.

The resistance control layer RAL is connected to the anode AN to be able to reduce the resistance of the anode AN. The resistance control layer RAL includes the first sub-contact hole S_CH1. The first sub-contact hole S_CH1 overlaps the first contact hole CH1. The first sub-contact hole S_CH1 may correspond to the first contact hole CH1 when viewed in cross section. The resistance control layer RAL contacts the anode AN in the first sub-contact hole S_CH1.

The resistance control layer RAL includes the first material. The first material may be a metal. Although not particularly limited, the first material may include any suitable material, e.g., at least one of Ag, Li, Ca, Al, Mg, W, or Ba.

The scattering layer SL is provided on the resistance control layer RAL. The scattering layer SL may scatter light emitted from the emission layer EML. For example, when the organic light emitting device OEL has a resonance distance, the scattering layer SL may scatter light emitted from the emission layer EML so that the organic light emitting device OEL is not resonant. That is, even when the organic light emitting device OEL has a resonance distance, the scattering layer SL may allow the organic light emitting device OEL to have a non-resonant structure.

The scattering layer SL includes the second sub-contact hole S_CH2. The second sub-contact hole S_CH2 overlaps each of the first contact hole CH1 and the first sub-contact hole S_CH1. The second sub-contact hole S_CH2 may correspond to each of the first contact hole CH1 and the first sub-contact hole S_CH1 when viewed in cross section. The scattering layer SL contacts the anode AN in the second sub-contact hole S_CH2.

The scattering layer SL may include a resin layer RL and scatterers SP included in the resin layer RL. Although not particularly limited, the resin layer RL may include any suitable material, e.g., a silicone resin or a photoresist resin. Although not particularly limited, the scatterers SP may include any suitable material, e.g., at least one of TiO₂, SiO₂, or ZnO.

The anode AN is provided on the scattering layer SL. The anode AN may be a pixel electrode or a positive electrode. The anode AN is connected to the resistance control layer RAL. The anode AN is connected to the resistance control layer RAL by the second sub-contact hole S_CH2.

The anode AN includes the second material different from the first material. The second material may be a transparent conductive oxide. Although not particularly limited, the second material may include any suitable material, e.g., at least one of indium tin oxide (ITO), indium zinc oxide (IZO), zinc oxide (ZnO), or indium tin zinc oxide (ITZO).

The hole transport region HTR is provided on the anode AN. The hole transport region HTR may include at least one of the hole injection layer HIL, the hole transport layer HTL, the buffer layer, or the electron blocking layer.

The emission layer EML is provided on the hole transport region HTR. The emission layer EML may have a single layer structure formed of a single material, a single layer structure formed of a plurality of materials different form each other, or a multi-layer structure having a plurality of layers formed of a plurality of materials different from each other.

The electron transport region ETR is provided on the emission layer EML. The electron transport region ETR may include, but not limited to, at least one of the hole blocking layer, the electron transport layer ETL, and the electron injection layer EIL.

The cathode CAT is provided on the electron transport region ETR. The cathode CAT may be a common electrode or a negative electrode. The cathode CAT may include a metal. Although not particularly limited, the cathode CAT may include any suitable material, e.g., at least one of Ag, Li, Ca, Al, Mg, W, or Ba.

The display device 10 according to an embodiment may be a top emission type display device. More specifically, the display device 10 according to an embodiment may emit light from the anode AN toward the cathode CAT.

The display device 10 according to an embodiment is designed to have a resonance distance, to include the scattering layer SL, and to allow light emitted from the emission layer EML to be non-resonant even when the cathode includes a metal.

Although not illustrated, the cathode CAT may be connected to an auxiliary electrode. When the cathode CAT is connected to the auxiliary electrode, the resistance of the cathode CAT may be reduced.

Referring to FIG. 6B, the display device 10 according to an embodiment may further include the auxiliary layer AL. The auxiliary layer AL is provided under the resistance control layer RAL. The auxiliary layer AL is provided between the passivation layer PL and the resistance control layer RAL.

The auxiliary layer AL includes the third sub-contact hole S_CH3. The third sub-contact hole S_CH3 overlaps each of the contact hole CH1 and the first and second sub-contact holes S_CH1 and S_CH2. The third sub-contact hole S_CH3 may correspond to each of the contact hole CH1 and the first and second sub-contact holes S_CH1 and S_CH2 when viewed in cross-section. The auxiliary layer AL contacts the anode AN in the third sub-contact hole S_CH3.

The auxiliary layer AL may include a transparent conductive oxide. Although not particularly limited, the auxiliary layer may include any suitable material, e.g., at least one of indium tin oxide (ITO), indium zinc oxide (IZO), zinc oxide (ZnO), or indium tin zinc oxide (ITZO).

The display device 10 according to an embodiment may further include the organic capping layer CPL. The organic capping layer CPL may be provided on the cathode CAT.

An existing display device generally does not include a scattering layer, thus having a limitation of a narrow viewing angle when a user views an image. In addition, since in the existing display device, a scattering layer is included within the anode, high power consumption is required by the scattering layer when an electric field is applied to the anode.

In contrast, since the display device according to an embodiment includes a scattering layer, a wide viewing angle may be provided to a user when the user views an image. In addition, in the display device according to an embodiment, since the scattering layer is provided under the anode while being separated from the anode, the display device may be driven with low power consumption. Furthermore, the display device according to an embodiment includes a resistance control layer electrically connected to the anode thus being able to be driven with low power consumption.

In an organic light emitting device according to an embodiment, the viewing angle may be improved. Further, in a display device according to an embodiment, the viewing angle may be improved.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An organic light emitting device, comprising:
a resistance control layer including a first material;
a scattering layer on the resistance control layer;
an anode including a second material different from the first material, the anode being on the scattering layer and electrically connected to the resistance control layer;
a hole transport region on the anode;
an emission layer on the hole transport region;
an electron transport region on the emission layer; and
a cathode on the electron transport region.

2. The organic light emitting device as claimed in claim 1, wherein:
the resistance control layer includes a first sub-contact hole, the scattering layer includes a second sub-contact hole overlapping the first sub-contact hole, and
the anode contacts the resistance control layer in the first sub-contact hole and the scattering layer in the second sub-contact hole.

3. The organic light emitting device as claimed in claim 1, wherein the scattering layer includes a resin layer, and scatterers within the resin layer.

4. The organic light emitting device as claimed in claim 3, wherein the scatterers include at least one of TiO₂, SiO₂, or ZnO.

5. The organic light emitting device as claimed in claim 1, wherein the first material is a metal.

6. The organic light emitting device as claimed in claim 5, wherein the first material includes at least one of Ag, Li, Ca, Al, Mg, W, or Ba.

7. The organic light emitting device as claimed in claim 1, wherein the second material is a transparent conductive oxide.

8. The organic light emitting device as claimed in claim 1, wherein the cathode includes a metal.

9. The organic light emitting device as claimed in claim 8, wherein the cathode includes at least one of Ag, Li, Ca, Al, Mg, W, or Ba.

10. The organic light emitting device as claimed in claim 1, further comprising an auxiliary layer under the resistance control layer, the auxiliary layer including a transparent conductive oxide.

11. The organic light emitting device as claimed in claim 10, wherein:
the resistance control layer includes a first sub-contact hole,
the scattering layer includes a second sub-contact hole overlapping the first sub-contact hole,
the auxiliary layer includes a third sub-contact hole overlapping each of the first and second sub-contact holes, and
the anode contacts the resistance control layer in the first sub-contact hole, the scattering layer in the second sub-contact hole, and the auxiliary layer in the third sub-contact hole.

12. The organic light emitting device as claimed in claim 1, further comprising an organic capping layer on the cathode.

13. The organic light emitting device as claimed in claim 1, wherein light is emitted from the anode toward the cathode.

14. The organic light emitting device as claimed in claim 1, wherein the hole transport region includes a hole injection layer, and a hole transport layer on the hole injection layer.

15. The organic light emitting device as claimed in claim 1, wherein the electron transport region includes an electron transport layer, and an electron injection layer on the electron transport layer.

16. A display device with a plurality of pixels, of which at least one includes an organic light emitting device, the organic light emitting device comprising:
a resistance control layer including a first material;
a scattering layer on the resistance control layer;
an anode including a second material different from the first material, the anode being on the scattering layer and electrically connected to the resistance control layer;
a hole transport region on the anode;
an emission layer on the hole transport region;
an electron transport region on the emission layer; and
a cathode on the electron transport region.

17. The display device as claimed in claim 16, further comprising:
a drain electrode connected to the anode; and
a passivation layer between the drain electrode and the anode, the passivation layer including a first contact hole,
wherein the resistance control layer includes a first sub-contact hole overlapping the first contact hole,
wherein the scattering layer includes a second sub-contact hole overlapping each of the first contact hole and the first sub-contact hole, and
wherein the drain electrode is connected to the anode by the first contact hole and the first and second sub-contact holes.

18. The display device as claimed in claim 17, further comprising an auxiliary layer between the passivation layer and the anode,
wherein the auxiliary layer includes a third sub-contact hole overlapping each of the first contact hole and the first and second sub-contact holes, and
wherein the drain electrode is connected to the anode by the first contact hole and the first, second, and third sub-contact holes.

19. The display device as claimed in claim 16, wherein the scattering layer includes a resin layer, and a scatterer in the resin layer.

20. The display device as claimed in claim 16, wherein the first material is a metal and the second material is a transparent conductive oxide, and the cathode includes a metal.
